(19) United States
(12) Patent Application Publication
(10) Pub. No.: US 2014/0352759 A1
(43) Pub. Date: Dec. 4, 2014

(54) REFLECTOR FOR A PHOTOVOLTAIC POWER MODULE

(71) Applicants: Brett Barnes, Victoria (AU); Joel Goodrich, Victoria (AU); Sam Carter, Victoria (AU)

(72) Inventors: Brett Barnes, Victoria (AU); Joel Goodrich, Victoria (AU); Sam Carter, Victoria (AU)

(73) Assignee: SOLAR SYSTEMS PTY LTD, Abbotsford, Victoria (AU)

(21) Appl. No.: 14/342,411

(22) PCT Filed: Aug. 21, 2012
(86) PCT No.: PCT/AU2012/000976

§ 371 Date: Jul. 11, 2014

Related U.S. Application Data
(60) Provisional application No. 61/530,402, filed on Sep. 2, 2011.

(51) Int. Cl. H01L 31/052; G02B 19/00; H01L 31/048; H01L 31/18

(52) U.S. Cl. CPC H01L 31/0525; H01L 31/18; G02B 19/0019; G02B 19/0042; H01L 31/048
USPC 136/246; 427/162; 216/2; 359/838; 438/72; 438/65

(57) ABSTRACT

A photovoltaic power module including a reflector, and methods for manufacturing the reflector. The photovoltaic power module includes a plurality of photovoltaic cells arranged in an array, including a photon source facing surface having a plurality of active areas that convert photons to electrical energy and a plurality of inactive areas that do not convert photons to electrical energy. The reflector covers at least one inactive area of a photon source facing surface, for reflecting photons that would otherwise have fallen on the inactive area onto an active area. The output of the photovoltaic power module may therefore be increased.

### FIELD OF THE INVENTION

The present invention relates to reflectors for photovoltaic power modules, photovoltaic power modules and methods for manufacturing such reflectors and photovoltaic power modules. The present invention has applicability in concentrated solar power systems, but is not to be taken to be limited to this example.

### BACKGROUND OF THE INVENTION

A concentrated solar power system includes a receiver and a concentrator. The concentrator reflects light incident on a relatively large surface area to a relatively small surface area of the receiver. The concentrator may take many different forms. For example, the concentrator may be a dish reflector that includes a parabolic array of mirrors that reflect light towards the receiver. The concentrator may alternatively be a heliostat reflector that includes a field of independently movable flat mirrors.

The receiver includes a plurality of photovoltaic power modules, each module including a dense array of photovoltaic cells for converting incident light into electrical energy. The receiver also includes an electrical circuit for transferring the electrical energy output of the photovoltaic cells and an inverter to convert the DC output of the photovoltaic cells to AC.

Each photovoltaic cell includes an active area that converts photons to electrical energy. However, reflected light falling within gaps between adjacent cells in the dense array is not absorbed and is thus wasted. To address this limitation, the photovoltaic cells are generally packed closely together in the dense array to minimise gaps between the cells. However, this may make it more difficult to manufacture a photovoltaic power module, as special processes are required to mount the cells close together and make electrical connections between the cells.

Another alternative is to use a photovoltaic cavity converter (PVCC) as the receiver. The PVCC includes a structure forming a cavity having a small light aperture at one end and a photovoltaic solar array located at the other end. Light enters the cavity through the aperture and photons can bounce around the inside of the cavity before impinging on the active areas of the photovoltaic cells and being converted to electrical energy.

It would be desirable to provide a photovoltaic power module that addresses one or more of the limitations described above or provides an alternative to existing photovoltaic power modules.

The above discussion of background art is included to explain the context of the present invention. It is not to be taken as an admission that any of the documents or other material referred to was published, known or part of the common general knowledge at the priority date of any one of the claims of this specification.

### SUMMARY OF THE INVENTION

The present invention provides a photovoltaic power module including a plurality of photovoltaic cells arranged in an array, the array of photovoltaic cells including a photon source facing surface having a plurality of active areas that convert photons to electrical energy and a plurality of inactive areas that do not convert photons to electrical energy, and a reflector covering at least one inactive area of the photon source facing surface, for reflecting photons that would otherwise have fallen on the inactive area onto an active area of the photon source facing surface.

The present invention further provides a reflector shaped to cover at least one inactive area of a photon source facing surface of an array of photovoltaic cells, for reflecting photons that would otherwise have fallen on the inactive area onto an active area of the photon source facing surface.

By utilising a reflector to direct photons from at least one inactive area of the photon source facing surface to an active area, the output of the photovoltaic power module may be increased. Photons that would otherwise have fallen on the inactive area and not been absorbed may be converted into electrical energy by an active area of a cell. The reflector may be considered to be a cell face optical concentrator.

The photovoltaic power module may be used in a concentrated solar power system, where a concentrator reflects light towards the module. Alternatively, the module may receive direct sunlight (single concentration) or low concentration light. For example, the module may include flat plate solar cells, such as large panels connected together. The invention is applicable to any form of solar power system.

The photovoltaic cells may be single or multi junction cells, and may be electrically connected in series, parallel or a combination of series and parallel, as would be understood by the skilled addressee. A plurality of photovoltaic cells is to be taken to mean two or more cells. An arrangement of cells in an array is to be taken to include any arrangement of the photovoltaic cells. For example, the cells may be arranged in a two dimensional array, in abutting relationship on a curved substrate, on a multi-surface substrate such as a cube or in a linear dense array of cells.

A plurality of active areas of the photon source facing surface includes an active area of each photovoltaic cell, also known as the “aperture” of the cell. For example, the active area may be composed of semiconductor materials, for example Group III-V materials, that absorb light and convert it to electricity when the light's energy matches the semiconductor's bandgap.

A plurality of inactive areas of the photon source facing surface may include one or more of gaps or spaces between photovoltaic cells, a busbar area on the cells, electrical contacts (such as wirebonds) which connect a top bus bar of each cell to a substrate pad and hence create an electrical path between the cells, and also mesa isolation around the edge of cells, to enable electrical isolation of the cells from each other for testing purposes. If photons impinge on inactive areas they are not absorbed and not converted to electrical energy.

The reflector covers at least one inactive area of the photon source facing surface. For example, the reflector may cover a single gap between two adjacent cells, the busbar area of the cells, the electrical contacts or wirebonds of one or more cells or any inactive area or areas of the photon source facing surface. The reflector may be shaped so as to cover the relevant area, and direct light onto an active area of the photon source facing surface.

In one embodiment, the reflector may cover the gaps between adjacent photovoltaic cells in the array. This may enable the cells to be positioned further apart and thus more easily manufactured and/or may enable the use of smaller cells in the array.

As described above, in existing photovoltaic power modules, photovoltaic cells are generally placed as close together as possible to minimise the wastage of photons falling in gaps between the cells. Cells are typically placed on a substrate by a pick and place robot which has a precision tolerance. The smaller the gap between adjacent cells, the greater the risk that the pick and place will misplace a cell. Cells placed too close together risk coming into contact and short circuiting. By using the reflector to reduce the problem of the gaps, the photovoltaic cells may be positioned further away from each other. This may reduce the required tolerance of the manufacturing process and enable standard manufacturing processes that require a specific gap between cells to be used. Also, larger gaps provide more space for wirebonds, which extend from a top electrode of each cell through the gap to an electrical circuit on a substrate.

Covering the gaps with a reflector also enables smaller cells to be used. Instead of trying to maximise the active area of the cells by using larger, less efficient and more costly cells, smaller and less costly cells may be used, with the reflector directing photons onto the active areas of the cells. Smaller cells are generally cheaper than larger cells as there is greater yield of parts from the same sized wafer, and smaller cells are generally more efficient than larger cells, but a limitation in using smaller cells is that the percentage of inactive area to active area increases, as the gaps do not scale with the size of the cell. For example, an array of 144 small cells having a cell pitch of 5 mm×5 mm would have an overall greater inactive area than an array of 36 large cells having a cell pitch of 10 mm×10 mm, even though the total active area of each array is about the same.

In an embodiment, the reflector covers substantially all of the plurality of inactive areas of the photon source facing surface. The reflector may thus cover all of the gaps, busbars and wirebonds. Inactive areas such as grid fingers on the cell surface to assist in current flow may or may not be covered. The fingers are generally thin and for ease of manufacturing it is preferred that the reflector not cover the fingers.

Covering substantially all of the plurality of inactive areas may provide a power output benefit.

For example, if the photon source facing surface has a total inactive area of 5-7% and 80% of the light that would otherwise have fallen on the inactive area is redirected to an active area, this may increase the output of the module by 4-5.6%.

The reflector may be grid shaped, the grid shape including a plurality of openings, each opening corresponding to an active area or aperture of a photovoltaic cell in the array. This may allow convenience in manufacturing the reflector, as it may be made in a single structure that may be attached to the array of cells. The reflector may include a front surface and a back surface, the back surface being adjacent to the plurality of photovoltaic cells, wherein a cross section of each opening in the reflector is larger on the front surface than on the back surface. The inactive areas may be covered by portions of the reflector between the back surface openings.

Each opening may be defined by one or more side walls extending between the back surface and the front surface of the reflector. The side walls may be straight, curved, parabolic or any other shape that enables the redirection of light falling on a side wall onto an active area of the photon source facing surface. The light may be redirected to an active area of a cell directly adjacent to the side wall or onto an active area of a cell that is not adjacent to the side wall. The side walls may join in an apex on the front surface of the reflector, such that most of the light falling on the reflector falls on a sidewall.

The reflector may be made from any reflective material, for example metal coatings or materials such as silver or aluminium, or dielectric coatings. It may be formed as a stand-alone structure such as a stamped foil.

The reflector may alternatively be formed using refractive methods. For example, the reflector may be graded or be composed of different refractive index materials to create a total internal reflective region, which reflects photons onto an active area of the photon source facing surface.

Alternatively, the reflector may be formed as a reflective coating applied to another structural element. Where a structural element is used, it may include one or more supports extending into gaps between the photovoltaic cells. The structural element may thus be supported on a substrate to which the cells are mounted. For convenience, the supports may extend on non-wire bond sides of the cells.

The structural element may be formed from silicon, from a polymer such as silicone, polycarbonate or possibly PMMA (acrylic), or from any other appropriate material such as moulded metal.

Where the structural element is formed from a polymer, a method of manufacturing a reflector may include moulding a polymer to include a substantially flat front surface and a back surface including a plurality of channels having side walls, and applying a reflective coating to the side walls of the plurality of channels, the reflective coating defining a reflector shaped to cover at least one inactive area of a photon source facing surface of an array of photovoltaic cells, for reflecting photons that would otherwise have fallen on the inactive area onto an active area of the photon source facing surface.

The reflective coating applied to the structural element may be deposited silver or any other reflective material as described above. The reflective coating may be applied by moulding, for example by moulding the polymer and reflective material together. Where the reflector is formed using refractive methods, the reflective coating may consist of 2 or more materials of different refractive index moulded together. Alternatively, the reflective coating may be applied by spraying or depositing (e.g. vacuum depositing) the coating on the side walls of the polymer channels. Areas where coating is not required may be masked before deposition, as would be understood by the skilled addressee.

The polymer may be moulded separately or on glass, such as on a glass cover of the photovoltaic power module. Where the polymer is soft, moulding on glass provides extra support to the polymer structural element. The method may further include attaching the polymer and applied reflector to a plurality of photovoltaic cells arranged in an array. The structural element or polymer may thus have a secondary purpose in the module, such as encapsulating the cell.

Where the structural element is formed from silicon, a method of manufacturing a reflector may include etching a silicon wafer to form a grid shape including a front surface, a back surface and a plurality of openings, each opening defined by one or more side walls extending between the back surface and the front surface, coating the side walls with a reflective coating defining a reflector shaped to cover at least one inactive area of a photon source facing surface of an array of photovoltaic cells, for reflecting photons that would otherwise have fallen on the inactive area onto an active area of the photon source facing surface.

Unlike the polymer example where the reflective coating is applied to a back surface of the polymer structural element, in the silicon example the reflective coating is applied to a front surface of the silicon structural element. The method may further include attaching the reflector to a plurality of photovoltaic cells arranged in an array, and encapsulating the reflector and photovoltaic cells with a polymer.

Similarly, where the structural element is a metal formed part, a method of manufacturing a reflector may include moulding metal (e.g. using metal injection moulding) to form a grid shape including a front surface, a back surface and a plurality of openings, each opening defined by one or more side walls extending between the back surface and the front surface and coating the side walls with a reflective coating defining a reflector shaped to cover at least one inactive area of a photon source facing surface of an array of photovoltaic cells. An advantage of using metal injection moulding in the process is that low coefficient of thermal expansion (CTE) metals may be used that are closely matched to the CTEs of the cells and substrate.

The structural element may alternatively be made of machined metal. In this case, a method of manufacturing a reflector may include machining metal to form a grid shape including a front surface, a back surface and a plurality of openings, each opening defined by one or more side walls extending between the back surface and the front surface, and coating the side walls with a reflective coating defining a reflector shaped to cover at least one inactive area of a photon source facing surface of an array of photovoltaic cells, for reflecting photons that would otherwise have fallen on the inactive area onto an active area of the photon source facing surface.

In each case, a photovoltaic power module may be manufactured by attaching the reflector to a plurality of photovoltaic cells arranged in an array, and encapsulating the reflector and photovoltaic cells with a polymer.

Also, in both the silicon and metal structural element embodiments, the method may include moulding a polymer onto the reflector, and attaching the polymer and reflector to a plurality of photovoltaic cells arranged in an array. For example, the reflector may be placed in a mould tool together with a glass cover, and moulded with a polymer. The end result would be the reflector positioned relative to the glass by the polymer.

The reflector or the reflector and structural element combination may be hollow, such that an inactive component may be positioned to sit within the body of the reflector, for example between the side walls of a grid structure. Alternatively, the reflector may be solid, such that an inactive component may be positioned to sit underneath the body of the reflector and the body of the reflector includes material between the side walls.

The present invention extends to a receiver including a plurality of photovoltaic power modules as described above.

### BRIEF DESCRIPTION OF THE DRAWINGS

Embodiments of the present invention will now be described, by way of example only, with reference to the accompanying drawings. It is to be understood that the particularity of the drawings does not supersede the generality of the preceding description of the invention.

FIG. 1 is a perspective view of a system for generating electrical power from solar radiation.

FIG. 2 is a front view of a receiver of the system of FIG. 1.

FIGS. 3a and 3b are isometric views of a reflector according to an embodiment of the invention.

FIGS. 4a and 4b are plan views of a photon source facing surface of an array of photovoltaic cells before (4a) and after (4b) attaching the reflector of FIGS. 3a and 3b.

FIG. 5 is a close up isometric view of a photon source facing surface of FIG. 4a.

FIG. 6 is a cross sectional view of a photovoltaic power module incorporating the reflector of FIGS. 3a and 3b.

FIG. 7 is an exploded isometric view of a photovoltaic power module according to another embodiment of the invention.

FIG. 8 is a plan perspective view and FIG. 9 is a side perspective view of the photovoltaic power module of FIG. 7.

### DETAILED DESCRIPTION

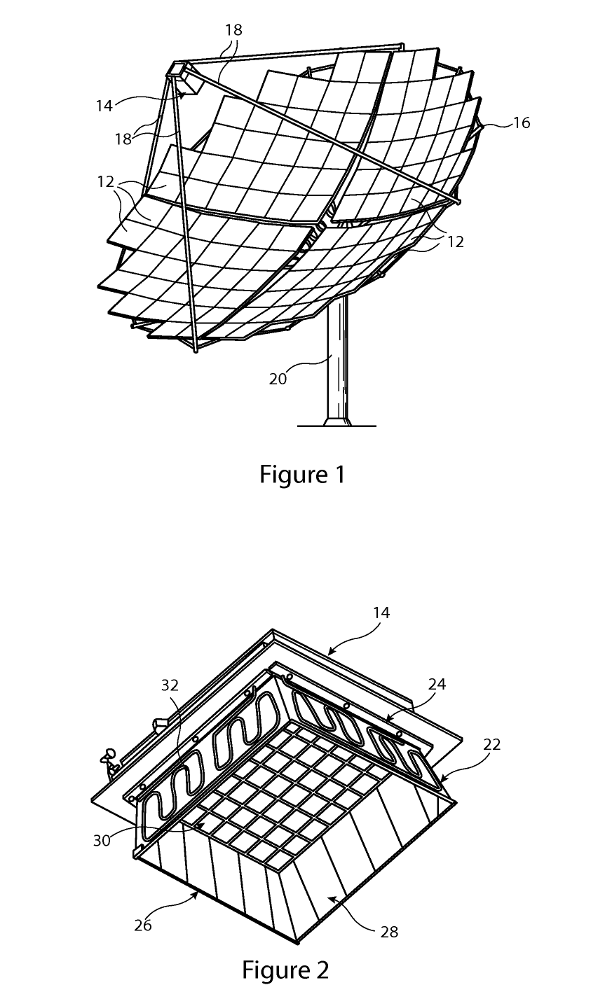

A concentrated solar power generating system 10 shown in FIG. 1 includes a concentrator 12 in the form of an array of mirrors that reflect solar radiation that is incident on the mirrors towards a receiver 14. The receiver 14 includes photovoltaic cells that convert reflected solar radiation into DC electrical energy. The receiver 14 also includes an electrical circuit (not shown) for the electrical energy output of the photovoltaic cells.

The concentrator 12 is mounted to a framework 16. A series of arms 18 extend from the framework 16 to the receiver 14 and locate the receiver as shown in FIG. 1. The system 10 further includes a support assembly 20 that supports the concentrator 12 and the receiver 14 in relation to a ground surface and for movement to track the sun; and a tracking system (not shown) that moves the concentrator 12 and the receiver 14 as required to track the sun. The receiver 14 also includes a coolant circuit which cools the receiver 14 with a coolant, preferably water, in order to maintain a safe operating temperature and to maximise the performance (including operating life) of the photovoltaic cells.

With reference to FIG. 2, the receiver 14 has a generally box-like structure. The receiver 14 also includes a solar flux modifier 22, which extends from a lower wall 24 of the box-like structure. The solar flux modifier 22 includes four panels 26 that extend from the lower wall 24 and converge toward each other. The solar flux modifier 22 also includes reflective surfaces 28 on the inwardly facing sides of the panels 26, for directing light onto the cells.

The receiver 14 includes a dense array of 2304 closely packed rectangular photovoltaic cells which are mounted to 64 square modules 30. In the example, each module 30 includes 36 photovoltaic cells arranged in a 6 cell by 6 cell array. The photovoltaic cells are mounted on each module 30 so that the photon source facing surface of the cell array is a continuous surface. The modules 30 are mounted to the lower wall 24 of the box-like structure of the receiver 14 so that, in this example, the exposed photon source facing surface of the combined array of photovoltaic cells is in a single plane.

Each module 30 includes a coolant flow path. The coolant flow path is an integrated part of each module 30 and allows coolant to be in thermal contact with the photovoltaic cells and extract heat from the cells. The coolant flow path of the modules 30 forms part of the coolant circuit. The coolant circuit also includes channels 32 on the flux modifier 22.

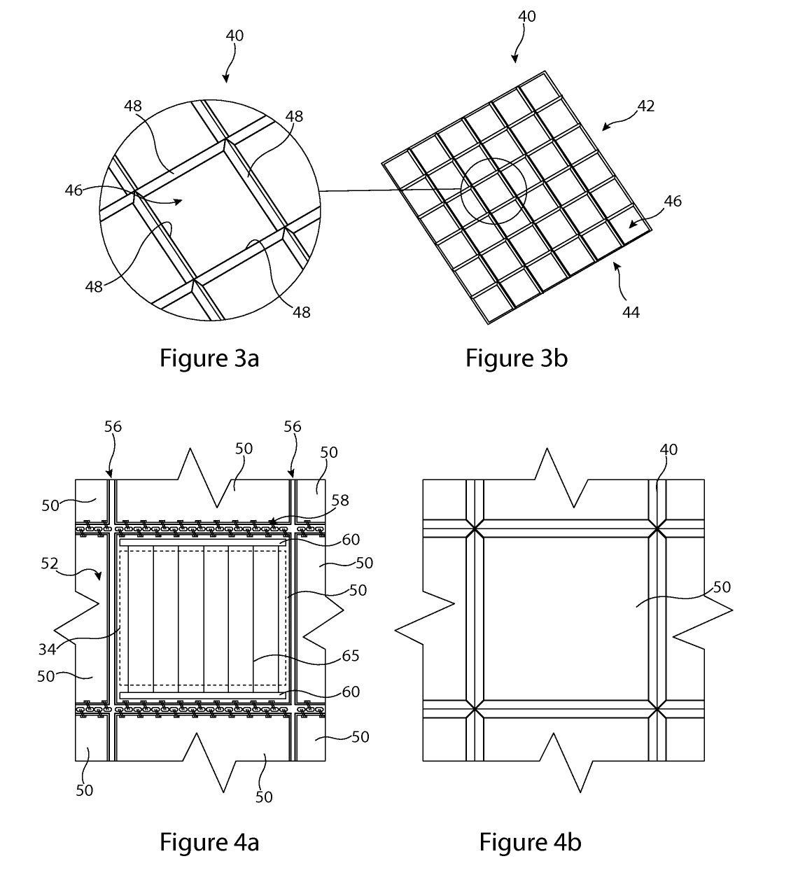

A reflector 40 according to an embodiment of the invention is shown in FIGS. 3a and 3b. The reflector 40 has a grid shape as can be seen in FIG. 3b. As can be seen, the reflector 40 is substantially planar, including a front surface 42 (a top plane of the reflector 40), a back surface 44 (a bottom plane of the reflector 40) and a plurality of openings 46. Each opening 46 is defined by four straight side walls 48 extending between the back surface 44 and the front surface 42 of the reflector 40. The straight side walls 48 slope at an angle to the front and back surfaces 42, 44 such that the cross section of the opening at the front surface 42 is larger than the cross section of the opening at the back surface 44. The body of the reflector 40 sits between the front and back surfaces 42 and 44.

The reflector 40 may be manufactured by first etching a silicon wafer to form a grid shape including a front surface, a back surface and a plurality of openings, each opening defined by four side walls extending between the back surface and the front surface. A (100) silicon wafer properly masked with a grid of silicon dioxide or silicon nitride which has been aligned to the 110 direction will etch in a caustic solution such as Potassium Hydroxide revealing sidewalls that are 54.75 degrees to the original surface of the wafer. If the etch proceeds long enough windows will be created through the wafer. The 54.75 degree slope of the sidewalls results in an opening having a cross section at the back surface of the wafer that is tan(54.75)(thickness of wafer) smaller than the cross section of the opening on the top surface. For example a wafer 1 mm thick would have a smaller back surface cross section of the opening by tan(54.75)(thickness of wafer)=1.415(1 mm)=1.415 mm. This dimension is the size of the inactive area that may be covered.

The side walls may then be coated with a reflective metal such as silver or aluminium and/or a dielectric mirror coating to increase the reflectivity of the sidewalls. As silicon is itself reflective, the coating step is optional. If the silicon is coated, it may be considered a structural element for providing a structure to the reflective metal reflector. Techniques for coating the side walls include vapour deposition, ion-beam sputtering and other thin film techniques, as would be understood by the skilled addressee.

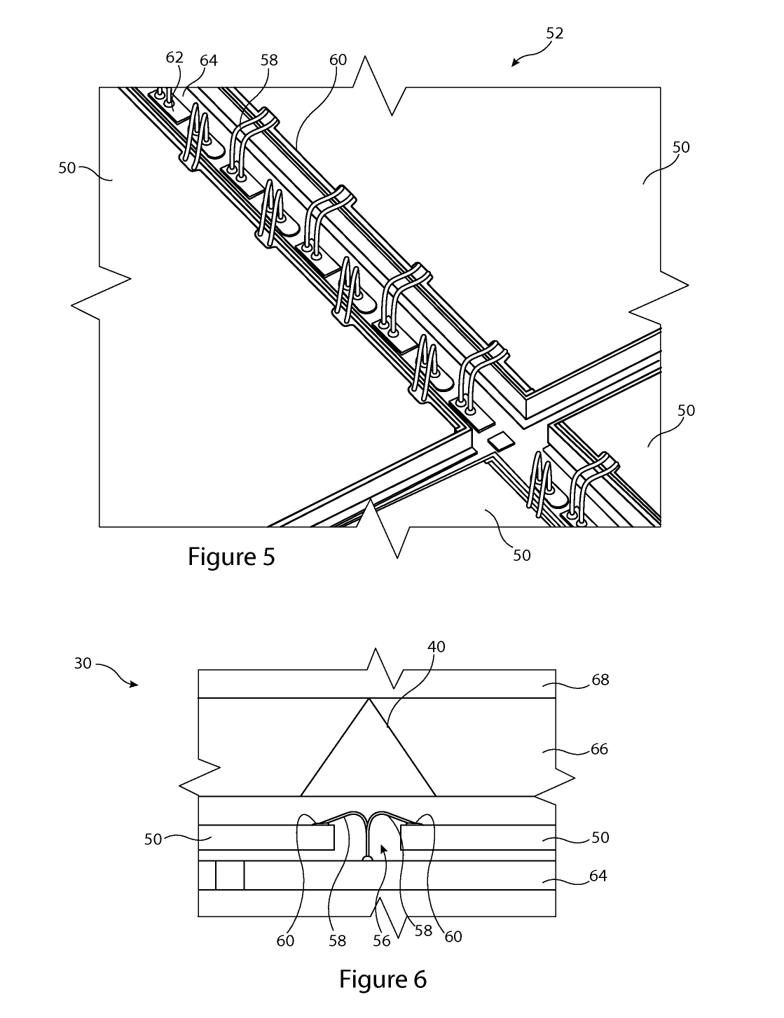

A close up partial view of some of the plurality of photovoltaic cells 50 arranged in an array as part of a module 30 can be seen in FIGS. 4a, 4b, 5 and 6. The array of photovoltaic cells 50 includes a photon source facing surface 52 having a plurality of active areas (such as apertures 54 of the photovoltaic cells 50) made of semiconductor material that converts photons to electrical energy and a plurality of inactive areas (such as gaps 56 between cells 50, wirebonds 58 and busbars 60 on the surface of the cell 50) that do not convert photons to electrical energy. The wirebonds 58 connect the busbars 60 on the surface of the cell 50 to metallised zones 62 on a substrate 64 to which the cells 50 are mounted. The metallised zones 62 form part of an electrical circuit for transferring power generated by the module 30. The cell 50 also includes fingers 65 extending across the surface of the cell 50 to promote the flow of current from the active area 54 to the busbars 60.

As shown in FIGS. 4b and 6, the reflector 40 is attached to the array of photovoltaic cells 50 such that the reflector 40 covers inactive areas 56, 58 and 60 of the photon source facing surface 52 of the array of photovoltaic cells 50, for reflecting photons that would otherwise have fallen on the inactive areas 56, 58 and 60 onto an active area 54 of the photon source facing surface 52. As can be seen in FIG. 6, in this embodiment the reflector 40 including the silicon structure is solid and positioned such that the inactive areas 56, 58 and 60 are below the solid reflector 40 and silicon structure. The reflector 40 covers the periphery of each cell 50 and the gaps 56 between the cells 50.

The silicon grid may include supports for extending into gaps between the photovoltaic cells to support the grid, for example on a substrate to which the cells are mounted. The supports may be vertical posts extending downwardly from the silicon grid at regular intervals. The supports may extend into gaps that do not include wirebonds 58, so that the supports do not interfere with the wirebonds 58. Typically, the wirebonds 58 are positioned along two edges of a cell 50, as shown in FIG. 4a.

Once the reflector 40 has been attached, a polymer 66 may then be applied to encapsulate the reflector 40 and photovoltaic cells 50 and optionally a glass cover 68 may be positioned on top of the photovoltaic power module 30. The reflector 40 may be held in place by the encapsulant 66. Alternatively or additionally, it may be attached to the substrate by a thermal adhesive such as a filled epoxy, or soldered to the substrate.

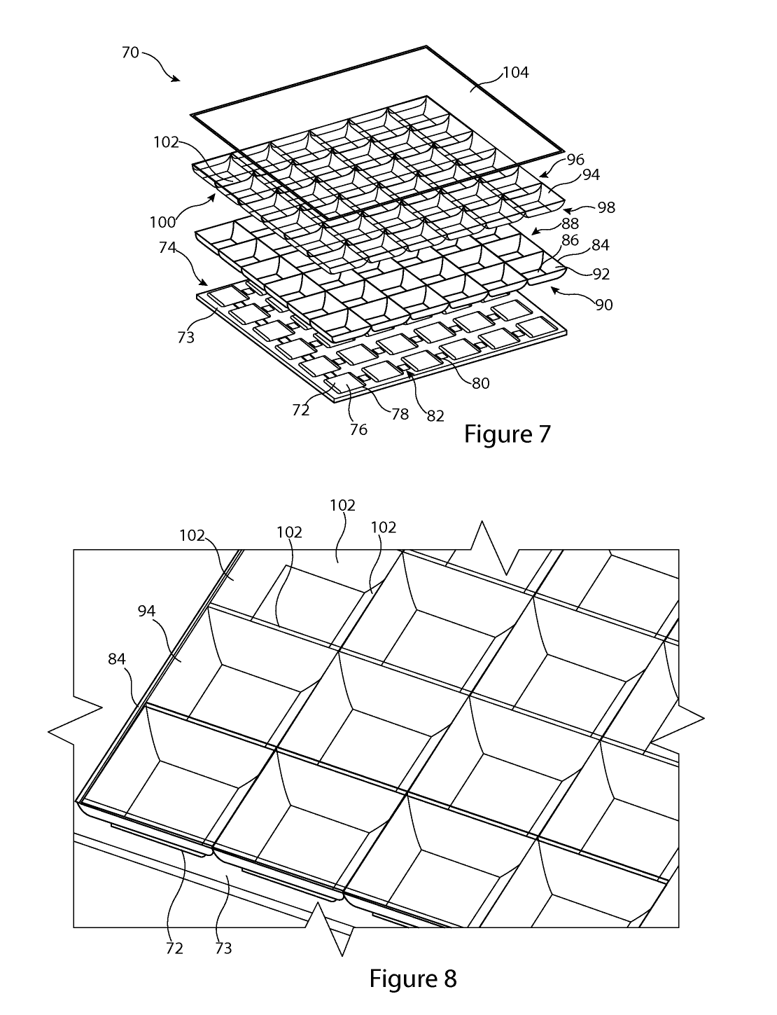

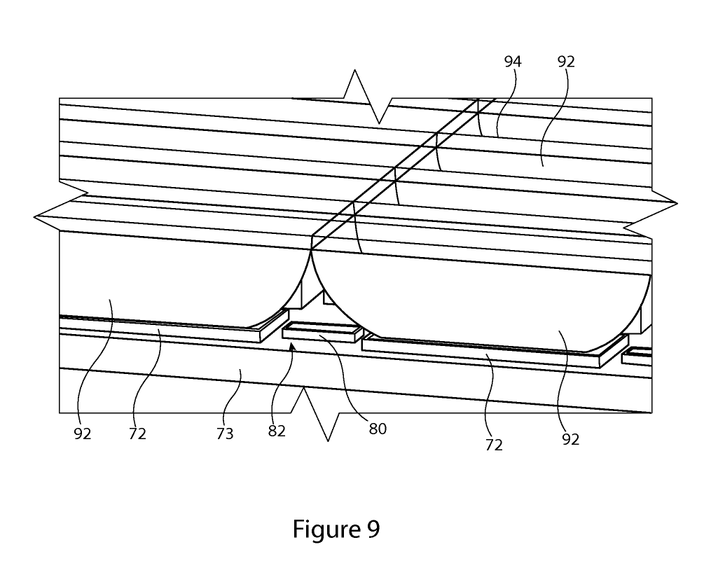

An exploded view of an alternative photovoltaic power module 70 is shown in FIG. 7. The module 70 includes a plurality of photovoltaic cells 72 arranged in an array on a substrate 73. The array of cells has a photon source facing surface 74 having a plurality of active areas (for example cell apertures 76) that convert photons to electrical energy, and a plurality of inactive areas (for example busbars 78 and gaps 82) that do not convert photons to electrical energy.

The module 70 further includes a reflector 84 that covers the inactive areas 78 and 82 of the photon source facing surface 74, for reflecting photons that would otherwise have fallen on the inactive areas 78 and 82 onto an active area 76 of the photon source facing surface 74.

Again, the reflector 84 is grid shaped, the grid shape including a plurality of openings 86, each opening 86 corresponding to an active area 76 of a photovoltaic cell 72 in the array. The reflector 84 includes a front surface 88 and a back surface 90, the back surface 90 being adjacent to the plurality of photovoltaic cells 72, wherein a cross section of each opening 86 in the reflector 84 is larger on the front surface 88 than on the back surface 90.

Each opening is defined by four curved, parabolic side walls 92 extending between the back surface 90 and the front surface 88 of the reflector 84. The shape of the side walls 92 may be seen more clearly in FIG. 9. In this example, the reflector 84 is hollow in that there is a gap between a side wall directing light onto one cell 72 and a side wall directing light onto an adjacent cell 72. Thus components such as bypass diodes 80 may sit between side walls 92 of the reflector 84. The use of the reflector 84 enables the gaps 82 between the cells 72 to be increased to a size to place bypass diodes 80 on the surface of the substrate 73, without suffering a corresponding reduction in output of the module 70.

The reflector 84 may be manufactured by moulding together a polymer and a reflective coating such as stamped silver foil. The polymer 94 may be moulded to include a substantially flat front surface 96 and a back surface 98 including a plurality of channels 100 having side walls 102. The stamped silver foil is moulded to the side walls 102 of the plurality of channels 100 to define the reflector 84. In contrast to the previous method, where a reflective coating was applied to a front surface of a silicon grid, in this method, the reflective coating is applied to a back surface of a moulded polymer. Suitable polymers include silicones and possibly PMMA (acrylic). Alternatives to moulding stamped silver foil include vacuum deposited metal and enhanced metal coatings or dielectric coatings.

The polymer may be moulded directly on a glass or other cover 104, or it may be moulded separately. The polymer and applied reflector 84 may then be attached to the array of photovoltaic cells 72. The polymer serves two purposes of providing a structural element on which the reflector may be moulded or deposited, and encapsulating the reflector 84 and photovoltaic cells 72.

It is to be understood that various alterations, additions and/or modifications may be made to the parts previously described without departing from the ambit of the present invention, and that, in the light of the above teachings, the present invention may be implemented in a variety of manners as would be understood by the skilled person.

1. A photovoltaic power module including:
a plurality of photovoltaic cells arranged in an array, the array of photovoltaic cells including a photon source facing surface having a plurality of active areas that convert photons to electrical energy and a plurality of inactive areas that do not convert photons to electrical energy, and
a reflector covering at least one inactive area of the photon source facing surface, for reflecting photons that would otherwise have fallen on the inactive area onto an active area of the photon source facing surface.

2. A photovoltaic power module as claimed in claim 1, wherein the inactive areas covered by the reflector includes gaps between adjacent photovoltaic cells in the array.

3. A photovoltaic power module as claimed in claim 1, wherein the reflector covers substantially all of the plurality of inactive areas of the photon source facing surface.

4. A photovoltaic power module as claimed in claim 1, wherein the reflector is grid shaped, the grid shape including a plurality of openings, each opening corresponding to an active area of a photovoltaic cell in the array.

5. A photovoltaic power module as claimed in claim 4, wherein the reflector includes a front surface and a back surface, the back surface being adjacent to the plurality of photovoltaic cells, wherein a cross section of each opening in the reflector is larger on the front surface than on the back surface.

6. A photovoltaic power module as claimed in claim 5, wherein each opening is defined by one or more straight side walls extending between the back surface and the front surface of the reflector.

7. A photovoltaic power module as claimed in claim 5, wherein each opening is defined by one or more curved side walls extending between the back surface and the front surface of the reflector.

8. A photovoltaic power module as claimed in claim 5, wherein each opening is defined by one or more parabolic side walls extending between the back surface and the front surface of the reflector.

9. A photovoltaic power module as claimed in claim 1, wherein the reflector is formed by a reflective coating applied to a structural element.

10. A photovoltaic module as claimed in claim 9, wherein the structural element includes one or more supports extending into gaps between the photovoltaic cells.

11. A photovoltaic module as claimed in claim 9, wherein the structural element is formed from silicon.

12. A photovoltaic module as claimed in claim 9, wherein the structural element is formed from a polymer.

13. A receiver including a plurality of photovoltaic power modules as claimed in claim 1.

14. A reflector shaped to cover at least one inactive area of a photon source facing surface of an array of photovoltaic cells, for reflecting photons that would otherwise have fallen on the inactive area onto an active area of the photon source facing surface.

15. A reflector as claimed in claim 14, the reflector having a grid shape including a front surface, a back surface and a plurality of openings, each opening defined by one or more side walls extending between the back surface and the front surface of the reflector, wherein a cross section of each opening in the reflector is larger on the front surface than on the back surface.

16. A method of manufacturing a reflector including:
moulding a polymer to include a substantially flat front surface and a back surface including a plurality of channels having side walls, and
applying a reflective coating to the side walls of the plurality of channels, the reflective coating defining a reflector shaped to cover at least one inactive area of a photon source facing surface of an array of photovoltaic cells, for reflecting photons that would otherwise have fallen on the inactive area onto an active area of the photon source facing surface.

17. A method as claimed in claim 16, wherein the polymer is moulded on glass.

18. A method of manufacturing a photovoltaic power module including:
moulding a polymer and applying a reflector as claimed in claim 16, and
attaching the polymer and applied reflector to a plurality of photovoltaic cells arranged in an array.

19. A method of manufacturing a reflector including:
etching a silicon wafer to form a grid shape including a front surface, a back surface and a plurality of openings, each opening defined by one or more side walls extending between the back surface and the front surface,
coating the side walls with a reflective coating defining a reflector shaped to cover at least one inactive area of a photon source facing surface of an array of photovoltaic cells, for reflecting photons that would otherwise have fallen on the inactive area onto an active area of the photon source facing surface.

20. A method of manufacturing a reflector including:
forming a grid shape by machining or moulding metal, the grid shape including a front surface, a back surface and a plurality of openings, each opening defined by one or more side walls extending between the back surface and the front surface, and
coating the side walls with a reflective coating defining a reflector shaped to cover at least one inactive area of a photon source facing surface of an array of photovoltaic cells, for reflecting photons that would otherwise have fallen on the inactive area onto an active area of the photon source facing surface.

21. (canceled)

22. A method of manufacturing a photovoltaic power module including:
manufacturing a reflector as claimed in claim 19;
attaching the reflector to a plurality of photovoltaic cells arranged in an array, and
encapsulating the reflector and photovoltaic cells with a polymer.

23. A method of manufacturing a photovoltaic power module including:
manufacturing a reflector as claimed in claim 19,
moulding a polymer onto the reflector, and
attaching the polymer and reflector to a plurality of photovoltaic cells arranged in an array.

24. A method as claimed in claim 23, wherein the polymer is moulded on glass.

25. A method of manufacturing a photovoltaic power module including:
manufacturing a reflector as claimed in claim 20;
attaching the reflector to a plurality of photovoltaic cells arranged in an array, and
encapsulating the reflector and photovoltaic cells with a polymer.

26. A method of manufacturing a photovoltaic power module including:
manufacturing a reflector as claimed in claim 20,
moulding a polymer onto the reflector, and
attaching the polymer and reflector to a plurality of photovoltaic cells arranged in an array.
